(19) United States
(12) Patent Application Publication
(10) Pub. No.: US 2026/0266940 A1
(43) Pub. Date: Sep. 10, 2026

(54) METHOD, SYSTEM, PROCESSING CIRCUITRY, AND COMPUTER PROGRAM PRODUCT FOR CALIBRATING FLIP ANGLES OF NON-EXCITATION RF TRANSMIT PULSES

(71) Applicant: CANON KABUSHIKI KAISHA, Tokyo (JP)

(72) Inventors: Andrew James WHEATON, Vernon Hills, IL (US); David Otto BRUNNER, Jona (CH)

(73) Assignee: CANON KABUSHIKI KAISHA, Tokyo (JP)

(21) Appl. No.: 19/069,516

(22) Filed: Mar. 4, 2025

(51) Int. Cl. G01R 33/565; G01R 33/54

(52) U.S. Cl. CPC G01R 33/56572; G01R 33/543

(57) ABSTRACT

A method, system, processing circuitry, and computer program product for calibrating flip angles of non-excitation RF pulses of a magnetic resonance imaging (MRI) pulse sequence based on spatial positions of the non-excitation RF pulses when used as part of a process in which MRI image data is captured (e.g., when using inversion recovery pulses).

### BACKGROUND OF THE INVENTION

### Field of the Invention

This disclosure relates to a method, system, processing circuitry, and computer program product for controlling a Magnetic Resonance Imaging (MRI) apparatus as described herein, and, in one embodiment, to a method, system, processing circuitry, and computer program product for calibrating flip angles of non-excitation RF pulses of an MRI pulse sequence based on spatial positions of the non-excitation RF pulses when used as part of a process in which MRI image data is captured.

### Discussion of the Background

In known MRI systems, MR transmit (Tx) coils have a characteristic B1 spatial homogeneity. They are typically highly homogeneous in the x-y plane but fall off in homogeneity in the z-direction the further the position is from isocenter (e.g., 80% of normalized B1 amplitude at ~125 mm from isocenter, ~75% of normalized B1 amplitude at ~150 mm from isocenter, and ~30% of normalized B1 amplitude at 250 mm). This causes an error in flip angles for regions far from isocenter. Axial field-echo (FE2D or FFE2D) with large z-coverage (T/L-spine) are sensitive to flip angle errors.

In addition, the Tx coil also has a characteristic frequency response in which for RF frequencies close to F0 (center frequency) the response is close to 1.0. However, typically, for frequencies far off-resonance, the transmit response is less efficient (<1.0). One source of off-resonance is the tuning of the resonant frequency of the transmit coil which may arise due to patient loading and/or inaccurate tuning of the transmit coil electrical elements (e.g. capacitors). Another source of off-resonance is the frequency offset (ΔF) of RF pulses as part of the pulse sequence. Intentional applications of AF may include off-resonance magnetization transfer pulses. A more common application of off-resonance is for spatially-selective RF selection. If the RF bandwidth of a spatially-selective RF pulse is high (e.g., when using a very sharp selection profile), ΔF is high (for slices far from isocenter), the transmission efficiency will also be reduced.

Some MRI imaging protocols utilize pre-pulses. Some prepulses have large z-offset AZ and/or large ΔF. Known pre-pulses include: inversion recovery (IR) pulses for FLAIR/STIR, presaturation pulses/flow-suppression presaturation pulses, and ASL/TSLIP tagging pulses.

For those 2D selective pre-pulses, due to Tx falloff caused by B1 ΔZ spatial response and ΔF frequency response, the flip angle will have an error dependent on its z-position. This will result in variable and reduced IQ depending on the z-position.

### BRIEF DESCRIPTION OF THE DRAWINGS

A more complete appreciation of the disclosure and many of the attendant advantages thereof will be readily obtained as the same becomes better understood by reference to the following detailed description when considered in connection with the accompanying drawings, wherein:

FIG. 1 is a schematic of an MRI apparatus;

FIG. 2 is flowchart of a process of adjusting a flip angle as described herein;

FIG. 3A is a schematic illustration of an original pulse sequence before applying the spatially-based flip angle modifications described herein;

FIG. 3B is a schematic illustration of modified pulse sequence after applying the spatially-based flip angle modifications described herein;

FIG. 4A is an image showing incomplete inversion due to Tx falloff when using an inversion recovery pulse that is not spatially adjusted;

FIG. 4B is an image showing improved inversion when using an IR pulse that is spatially adjusted to reduce the effects of Tx falloff;

FIG. 5 is a block diagram showing a pickup loop measuring a B1 field of a whole body coil; and

FIG. 6 is a block diagram showing a power sensor and a directional coupler for measuring a B1 field of a whole body coil.

### DETAILED DESCRIPTION

The terms “a” or “an”, as used herein, are defined as one or more than one. The term “plurality”, as used herein, is defined as two or more than two. The term “another”, as used herein, is defined as at least a second or more. The terms “including” and/or “having”, as used herein, are defined as comprising (i.e., open language). Reference throughout this document to “one embodiment”, “certain embodiments”, “an embodiment”, “an implementation”, “an example” or similar terms means that a particular feature, structure, or characteristic described in connection with the embodiment is included in at least one embodiment of the present disclosure. Thus, the appearances of such phrases or in various places throughout this specification are not necessarily all referring to the same embodiment. Furthermore, the particular features, structures, or characteristics may be combined in any suitable manner in one or more embodiments without limitation.

The present disclosure is related to a method, system, and non-transitory computer-readable storage medium storing computer-readable instructions for calibrating flip angles of non-excitation RF pulses of an MRI pulse sequence based on spatial positions of the non-excitation RF pulses when used as part of a process in which MRI image data is captured. In one embodiment, it can be appreciated that the present disclosure can be viewed as a system. While the present exemplary embodiments will refer to an MRI apparatus, it can be appreciated that other system configurations can use other medical imaging apparatuses (e.g., CT systems and combined MRI/CT systems).

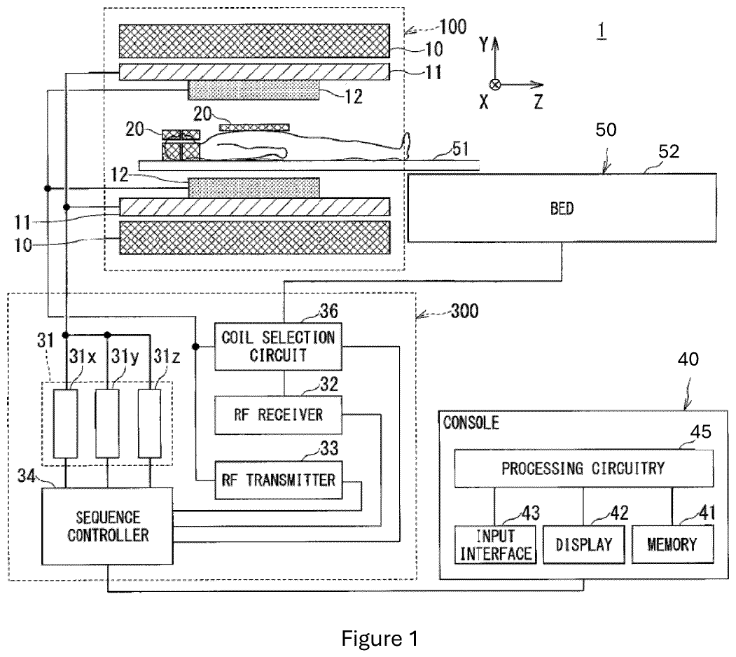

Referring now to the drawings, FIG. 1 is a block diagram illustrating overall configuration of an MRI apparatus 1. The MRI apparatus 1 includes a gantry 100, a control cabinet 300, a console 40, a bed 50, and radio frequency (RF) coils 20. The gantry 100, the control cabinet 300, and the bed 50 constitute a scanner, i.e., an imaging unit.

The gantry 100 includes a static magnetic field magnet 10, a gradient coil 11, and a whole body (WB) coil 12, and these components are housed in a cylindrical housing. The bed 50 includes a bed body 52 and a table 51.

The control cabinet 300 includes three gradient coil power supplies 31 (31 x for an X-axis, 31 y for a Y-axis, and 31 z for a Z-axis), a coil selection circuit 36, an RF receiver 32, an RF transmitter 33, and a sequence controller 34.

The console 40 includes processing circuitry 45, a memory 41, a display 42, and an input interface 43. The console 40 functions as a host computer.

The static magnetic field magnet 10 of the gantry 100 is substantially in the form of a cylinder and generates a static magnetic field inside a bore into which an object such as a patient is transported. The bore is a space inside the cylindrical structure of the gantry 100. The static magnetic field magnet 10 includes a superconducting coil inside, and the superconducting coil is cooled down to an extremely low temperature by liquid helium. The static magnetic field magnet 10 generates a static magnetic field by supplying the superconducting coil with an electric current provided from a static magnetic field power supply (not shown) in an excitation mode. Afterward, the static magnetic field magnet 10 shifts to a permanent current mode, and the static magnetic field power supply is separated. Once it enters the permanent current mode, the static magnetic field magnet 10 continues to generate a strong static magnetic field for a long time, for example, over one year.

The gradient coil 11 is also substantially in the form of a cylinder and is fixed to the inside of the static magnetic field magnet 10. This gradient coil 11 applies gradient magnetic fields (for example, gradient pulses) to the object in the respective directions of the X-axis, the Y-axis, and the Z-axis, by using electric currents supplied from the gradient coil power supplies 31 x, 31 y, and 31 z.

The bed body 52 of the bed 50 can move the table 51 in the vertical direction and in the horizontal direction. The bed body 52 moves the table 51 with an object placed thereon to a predetermined height before imaging. Afterward, when the object is imaged, the bed body 52 moves the table 51 in the horizontal direction so as to move the object to the inside of the bore.

The WB body coil 12 is shaped substantially in the form of a cylinder so as to surround the object and is fixed to the inside of the gradient coil 11. The WB coil 12 applies RF pulses transmitted from the RF transmitter 33 to the object. Further, the WB coil 12 receives magnetic resonance signals, i.e., MR signals emitted from the object due to excitation of hydrogen nuclei.

The MRI apparatus 1 may include the RF coils 20 as shown in FIG. 1 in addition to the WB coil 12. Each of the RF coils 20 is a coil placed close to the body surface of the object. There are various types for the RF coils 20. For example, as the types of the RF coils 20, as shown in FIG. 1, there are a body coil attached to the chest, abdomen, or legs of the object and a spine coil attached to the back side of the object. As another type of the RF coils 20, for example, there is a head coil for imaging the head of the object. Although most of the RF coils 20 are coils dedicated for reception, some of the RF coils 20 such as the head coil are a type that performs both transmission and reception. The RF coils 20 are configured to be attachable to and detachable from the table 51 via a cable.

The RF transmitter 33 generates each RF pulse on the basis of an instruction from the sequence controller 34. The generated RF pulse is transmitted to the WB coil 12 and applied to the object. An MR signal is generated from the object by the application of one or plural RF pulses. Each MR signal is received by the RF coils 20 or the WB coil 12.

The MR signals received by the RF coils 20 are transmitted to the coil selection circuit 36 via cables provided on the table 51 and the bed body 52. The MR signals received by the WB coil 12 are also transmitted to the coil selection circuit 36.

The coil selection circuit 36 selects MR signals outputted from each RF coil 20 or MR signals outputted from the WB coil depending on a control signal outputted from the sequence controller 34 or the console 40.

The selected MR signals are outputted to the RF receiver 32. The RF receiver 32 performs analog to digital (AD) conversion on the MR signals, and outputs the converted signals to the sequence controller 34. The digitized MR signals are referred to as raw data in some cases. The AD conversion may be performed inside each RF coil 20 or inside the coil selection circuit 36.

The sequence controller 34 performs a scan of the object by driving the gradient coil power supplies 31, the RF transmitter 33, and the RF receiver 32 under the control of the console 40. When the sequence controller 34 receives raw data from the RF receiver 32 by performing the scan, the sequence controller 34 transmits the received raw data to the console 40.

The sequence controller 34 includes processing circuitry (not shown). This processing circuitry is configured as, for example, a processor for executing predetermined programs or configured as hardware such as a field programmable gate array (FPGA) or an application specific integrated circuit (ASIC).

The console 40 includes the memory 41, the display 42, the input interface 43, and the processing circuitry 45 as described above.

The memory 41 is a recording medium including a read-only memory (ROM) and a random access memory (RAM) in addition to an external memory device such as a hard disk drive (HDD) and an optical disc device. The memory 41 stores various programs executed by a processor of the processing circuitry 45 as well as various types of data and information.

The input interface 43 includes various devices for an operator to input various types of information and data, and is configured of a mouse, a keyboard, a trackball, and/or a touch panel, for example.

The display 42 is a display device such as a liquid crystal display panel, a plasma display panel, and an organic EL panel.

The processing circuitry 45 is a circuit equipped with a central processing unit (CPU) and/or a special-purpose or general-purpose processor, for example. The processor implements various functions described below by executing the programs stored in the memory 41. The processing circuitry 45 may be configured as hardware such as an FPGA and an ASIC. The various functions described below can also be implemented by such hardware. Additionally, the processing circuitry 45 can implement the various functions by combining hardware processing and software processing based on its processor and programs.

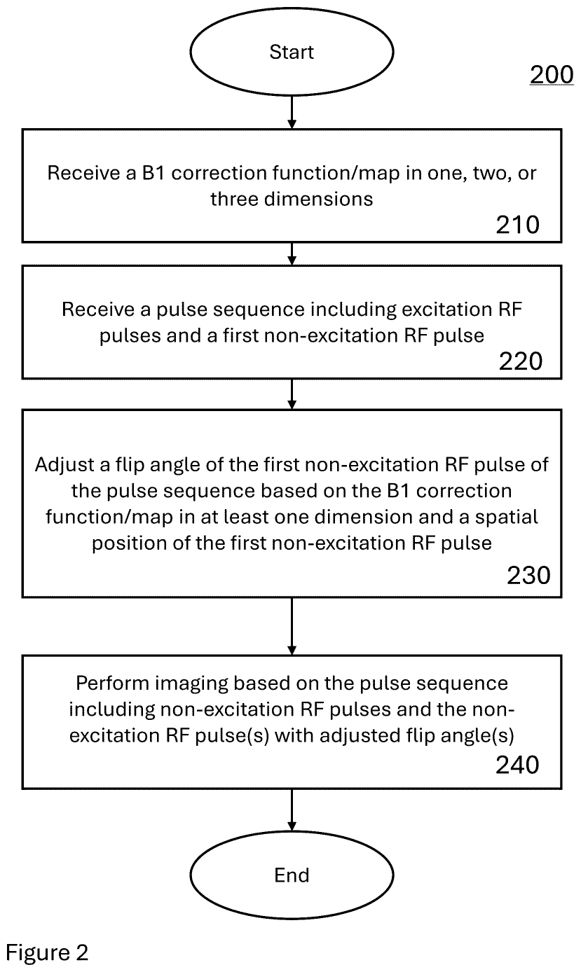

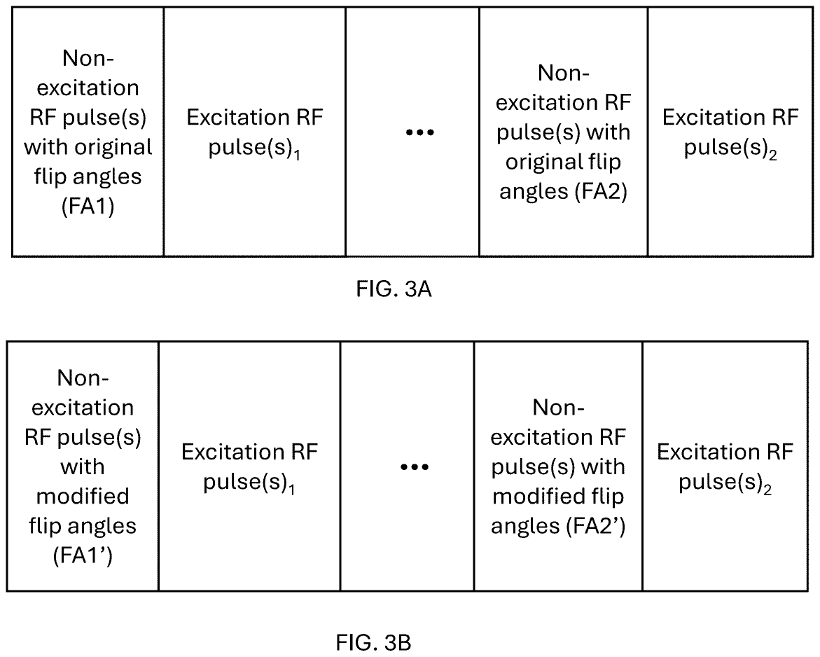

FIG. 2 is a flowchart showing a generalized process as described herein. In method 200, the process begins in step 210 by receiving a B1 correction function/map (as a function of spatial position) in at least one dimension. In one embodiment, the B1 correction function/map can be received in one, two, or three dimensions on a per-patient basis prior to imaging the patient. In step 220, the system receives a pulse sequence (as shown in FIG. 3A) including excitation pulses and at least a first non-excitation RF pulse that are selected based on the imaging sequence to be performed. (FIG. 3A shows first and second non-excitation RF pulses with corresponding flip angles within the same pulse sequence.) In step 230, a flip angle of at least the first non-excitation RF pulse of the pulse sequence is adjusted based on the B1 correction function/map in at least one dimension and a spatial position of the first non-excitation RF pulse. (FIG. 3B shows first and second non-excitation RF pulses with corresponding adjusted flip angles within the same pulse sequence.) Optionally, a flip angle of at least one of the excitation RF pulses of the pulse sequence can be adjusted based on the B1 correction function/map in at least one dimension and a spatial position of the at least one of the excitation RF pulses of the pulse sequence. In step 240, imaging is performed based on the pulse sequence including excitation RF pulses and the non-excitation RF pulse(s) with adjusted flip angle(s). In addition, when the flip angle of at least one of the excitation RF pulses of the pulse sequence has been adjusted, imaging can be performed with the adjusted flip angle for the at least one of the excitation RF pulses as well.

Additional details of the above general steps are provided below. As would be appreciated by those of skill in the art, the order of steps 210 and 220 may be reversed. In one embodiment, the steps of method 200 are all performed after a patient is placed onto a bed 50 of the MRI apparatus 1. In an alternate embodiment, either or both of steps 210 and 220 can be performed before the patient is placed onto the bed 50. In one such alternate embodiment, step 220 is performed before the patient is placed on the bed 50, and step 210 is performed after the patient has been placed on the bed 50.

In an embodiment of step 210 that is performed on a per-patient basis, during an imaging pre-scan process specific to each patient, AZ Tx falloff is received in one, two, or three dimensions by scanning the patient on the bed 50, Exemplary scanning techniques include, but are not limited to, (1) a sagittal B1 projection and (2) a set of axial B1 projections. Scans using sagittal B1 projections are short (e.g., 100 milliseconds) and do not substantially increase the imaging times of each patient. In performing a sagittal B1 projection with readout in the z-direction, a Bloch-Siegert method can be used which reads out a single projection in the z-direction indicating Tx falloff. By performing this data capture on a per-patient basis, the system captures the effect of patient loading resulting in a per-patient B1 spatial distribution. The received data can be used to create a normalized array/plot of the B1 distribution (in the z-direction). Such data can be used as a lookup table (indexed by position in the z direction) acting as the B1 correction function/map. Alternatively, the received data can be fitted to a function that approximates the correction for a particular position in the z direction, and the fitted function can be received by the method. In embodiments using data from more than one dimension, the lookup table or other function/map can be indexed by the “n” dimensions for which correction data is obtained. (As used herein, “function” is intended to mean a function of any dimension, and “map” is intended to mean a function of at least two dimensions.)

In an alternate embodiment, the Bloch-Siegert method can instead be applied to a phantom to be used as a system calibration. In such an embodiment, the Tx falloff pattern is determined by the Tx coil hardware, not the patient loading or patient B1 distribution, so the calibration data need not be received on a per-patient basis. For example, a system-specific lookup table is generated (and may be regenerated periodically to accommodate for changes to hardware related to the Tx coil including the RF shield, RF amplifier, and Tx coil itself.

In either the patient-specific or the system-wide embodiment, the received B1 data is used to create a profile of B1 efficiency vs. spatial z-position that can be used as a B1 correction function/map B1(z). The intended flip angle of each spatially-selective non-excitation RF pulse can then be adjusted in step 230 (e.g., by dividing the intended flip angle by the measured B1 correction function/map at the z-position (i.e., spatial position) of the non-excitation RF pulse). For example, the generation of a modified flip angle (Flip_{modified}) can be given by:

$${Flip}_{modified} = \frac{{Flip}_{intended}}{B 1 ( z )} .$$

As an alternative, the B1 correction function/map can be an inverse of the normalized spatially-varying measured B1 values (denoted as B1′) such that a division operation is avoided and (Flip_{modified}) can be given by:

$${Flip}_{modified} = {Flip}_{intended} * B {1}^{′} ( z ) .$$

Instead of using only one-dimensional correction data, the variations in B1 data can be captured/measured in plural dimensions. For example, in one alternative embodiment, a set of axial 1D projections at different z-positions is obtained and recorded, and the time to acquire the set of 1D projections is reasonably fast (e.g., 30 z-positions×100 ms=3 seconds) which does not significantly increase the total scanning time. The obtained data can be stored as a two-dimensional lookup table.

A further alternative embodiment captures and records projections oriented along the slice-selection axis of each non-excitation RF pulse. Such an embodiment automatically incorporates the actual slice position of the non-excitation RF pulse. While only a portion of the non-excitation RF pulse's selected slice can be improved using this method when the non-excitation RF pulse is oblique to the z-axis, there is nonetheless a partial improvement.

In yet another embodiment, the method acquires and records at least one of (1) a set of 2D B1 maps and (2) a 3D B1 map. In yet another embodiment, step 210 does not acquire the data for the B1 correction function/map but rather generates the data through simulation of the Tx falloff pattern using electromagnetic simulation software (e.g., by using Sim4Life, ZMT Zurich MedTech AG, Zurich, Switzerland).

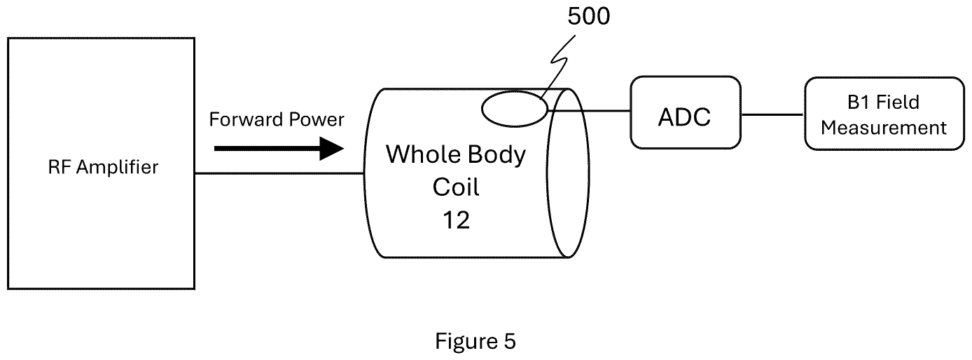

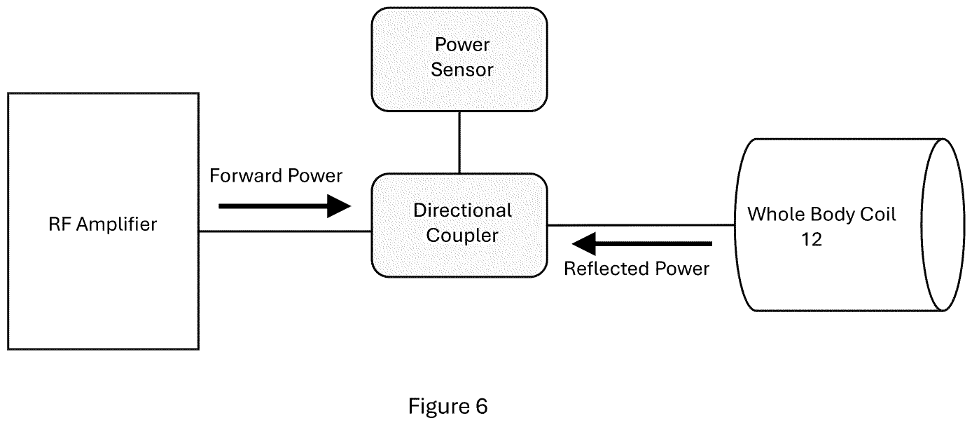

Furthermore, as part of step 210 (or as an alternative to the processes disclosed above), the AF response for the patient can be received as the B1 correction function/map by using a network analyzer to measure the quality factor (Q) of the whole body coil (WBC) 12 as a measure of transmission efficiency. Alternative methods of measuring the frequency response of the WBC 12 include measuring the B1 field (e.g., using an analog-to-digital converter (ADC) and at least one pickup loop 500 as shown in FIG. 5) or measuring the reflected power from the WBC 12 (e.g., using power sensor coupled to a directional coupler as shown in FIG. 6).

Finally, the ΔZ and/or ΔF information can then be used together to create a B1 correction function/map.

In steps 220 and 230, the first non-excitation RF pulse of the pulse sequence can be any spatially-selective RF pulse. For example, one type of such a spatially-selective RF pulse is a spatially-selective pulse where the selection is in the same geometry alignment as the imaging slices. An example of such a pulse is an IR pulse for FLAIR or STIR imaging. Another type of spatially-selective RF pulse is a pulse where the selection is in a different geometry alignment as the imaging slices such as a spatially-selective presaturation pulse.

Another type of spatially-selective pulse is a spatially-selective tagging pulse where selection affects moving spins that will move/flow into the imaging slices, e.g., blood or CSF. Such a tagging pulse includes an arterial spin labelling (ASL) tagging pulse and a TSLIP tagging pulse. Furthermore, the spatially-selective pulse can be a spatially-selective saturation pulse (where the selection of the pulse is meant to reduce or remove signal from outside of the imaging slice(s)). One such pulse is a flow-suppression saturation pulse. Moreover, more than one non-excitation RF pulse can be used and adjusted in the same pulse sequence. Exemplary pulse sequences that can be used according to the present invention include, but are not limited to, pulse sequences for axial imaging with large z-coverage (e.g. thoracic/lumbar spine).

In one embodiment, the correction of the flip angles of the RF pulses in a pulse sequence are limited to only the non-excitation RF pulses (or to the pre-pulses). In this way, the specific absorption rate (SAR) of the pulse sequence is not increased greatly as the power of the non-excitation RF pulses is typically only a small percentage of the imaging pulse RF power. For example, for the standard FLAIR protocol with adiabatic inversion pulses, the SAR is only increased 1.25% when adjusting the FLAIR inversion pulse only compared to conventional FLAIR sequence where the inversion pulse is uncorrected. By comparison, known systems experiencing Tx falloff have been known to use adiabatic inversion pulses with nominal flip angles much greater than the adiabatic threshold) (~220° such as flip angles of 240° or 270°. This results in full inversion across the entire z-range, but it is an inefficient use of SAR due to the overflipping of the inversion pulse to accommodate the expected Tx falloff. Instead, by measuring the Tx falloff, the individual inversion flip angles can be reduced and adjusted more efficiently based on their respective z-positions. Therefore, this method can be used to reduce SAR when using adiabatic RF imaging. For example, by reducing the inversion flip angle from 270° without correction to 220° with correction, 5% SAR reduction is achieved.

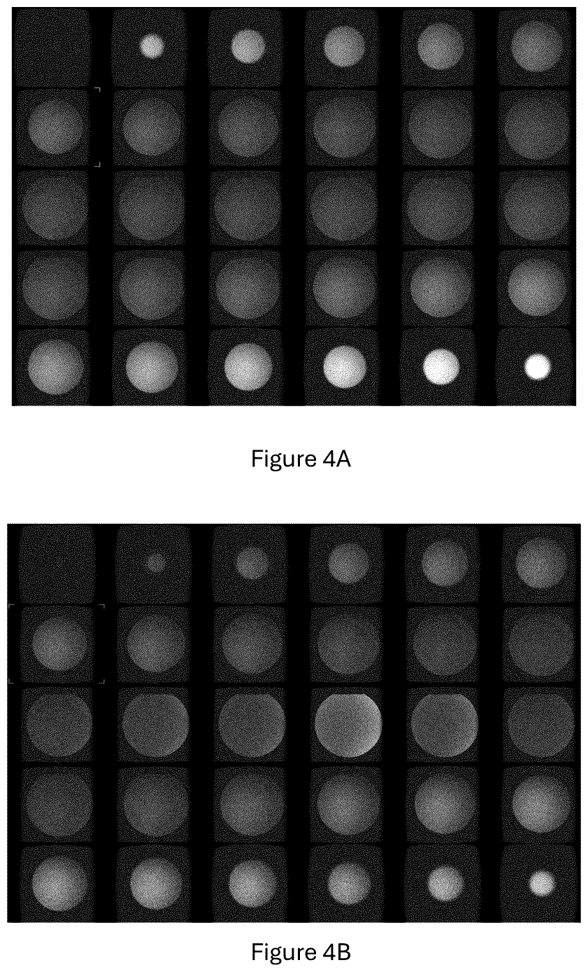

FIG. 4A is an image showing incomplete inversion due to Tx falloff when using an inversion recovery pulse that is not spatially adjusted. By comparison, FIG. 4B is an image showing improved inversion when using an IR pulse that is spatially adjusted to reduce the effects of Tx falloff as described herein. FIGS. 4A and 4B are FLAIR image sets on 30 cm oil spheres with a whole-body coil (WBC) receiver (Rx) obtained from a 1.5T Orian system of the Applicant. The images were obtained with TI/TR=100 ms/10000 ms, Slice thickness/gap=5/5 mm, and edge slices are positioned at ±15 cm from isocenter. The effect of Tx falloff is observed in FIG. 4A in the high signal near edge slices caused by the incomplete inversion caused by the Tx falloff effect. In the image set of FIG. 4B obtained using adjusted flip angles, the signal intensity is uniform across all slice positions, indicating accurate flip angles for all IR pulses at changing slice locations.

The method described herein has enhanced applicability to pulse sequences for extra wide bore systems (e.g., >75 cm). In such an embodiment, the relative size of the Tx coil can affect Tx dropoff, and the method described herein can be applied to such systems to reduce image quality degradation when using shorter Tx coils. For example, a typical z-FOV is 30 cm and is used with a Tx coil having a z-length of 45 or 50 cm. This creates a falloff in z-direction as described above (e.g., with an approximate 25% reduction at +/−15 cm). However, if a shorter Tx coil of 30 cm z-length were used, it is estimated that the corresponding falloff would be much greater (e.g., 50 or 60%). Thus, the present method would produce images with better image quality in the presence of shorter Tx coils.

Embodiments of the present disclosure may also be as set forth in the following parentheticals.

(1) A method for adjusting a flip angle of a first non-excitation RF pulse of a pulse sequence including excitation RF pulses and the first non-excitation RF pulse when imaging using a magnetic resonance imaging apparatus, the method including, but not limited to: receiving a B1 correction function in a first dimension; receiving the pulse sequence including the excitation RF pulses and the first non-excitation RF pulse; and adjusting the flip angle of the first non-excitation RF pulse based on the received B1 correction function and based on a first spatial position of the first non-excitation RF pulse.

(2) The method according to (1), further including, but not limited to, performing imaging using the pulse sequence including the adjusted flip angle of the first non-excitation RF pulse of the pulse sequence.

(3) The method according to either one of (1) or (2), wherein the adjusting the flip angle of the first non-excitation RF pulse based on the received B1 correction function and based on the first spatial position of the first non-excitation RF pulse consists of adjusting the flip angle of the first non-excitation RF pulse based on the received B1 correction function and based on the first spatial position of the RF non-excitation pulse without adjusting flip angles of the excitation RF pulses based on the received B1 correction function.

(4) The method according to any one of (1)-(3), wherein the adjusting the flip angle of the first non-excitation RF pulse based on the received B1 correction function and based on the first spatial position of the first non-excitation RF pulse includes, but not limited to, dividing the flip angle of the first non-excitation RF pulse by a correction factor of the received B1 correction function corresponding to the first spatial position of the first non-excitation RF pulse.

(5) The method according to any one of (1)-(4), wherein the first non-excitation RF pulse precedes at least one of the excitation RF pulses of the pulse sequence.

(6) The method according to any one of (1)-(5), wherein the first non-excitation RF pulse is a spatially-selective RF pulse where selection of the spatially-selective RF pulse is in a same geometry alignment as corresponding imaging slices.

(7) The method according to (6), wherein the spatially-selective RF pulse is an inversion pulse.

(8) The method according to (7), wherein the inversion pulse is a FLAIR pulse.

(9) The method according to (7), wherein the inversion pulse is a STIR pulse.

(10) The method according to (6), wherein the spatially-selective saturation pulse is an RF pulse for signal presaturation.

(11) The method according to (6), wherein the spatially-selective RF pulse is a spatially-selective tagging pulse.

(12) The method according to (11), wherein the spatially-selective tagging pulse is an arterial spin labelling tagging pulse.

(13) The method according to (6), wherein the spatially-selective RF pulse is a spatial presaturation pulse.

(14) The method according to (13), wherein the spatial presaturation pulse is a flow suppression pulse.

(15) The method according to any one of (1)-(14), wherein receiving the B1 correction function in the first dimension includes, but is not limited to, receiving a result of a one-dimensional B1 projection.

(16) The method according to any one of (1)-(14), wherein receiving the B1 correction function in the first dimension includes, but is not limited to, receiving results of a set of one-dimensional B1 projections at different distances from the isocenter to produce a B1 correction function in two dimensions.

(17) The method according to any one of (1)-(14), wherein receiving the B1 correction function in the first dimension includes, but is not limited to, receiving a result of a frequency response of a transmit coil.

(18) The method according to any one of (1)-(17), further including, but not limited to, adjusting a flip angle of a second non-excitation RF pulse of the pulse sequence based on the received B1 correction function and based on a second spatial position of the second non-excitation RF pulse.

(19) The method according to any one of (1), (2), and (4)-(18), further including, but not limited to, adjusting a flip angle of a first excitation RF pulse of the pulse sequence based on the received B1 correction function and based on a second spatial position of the first non-excitation RF pulse.

(20) The method according to any one of (1)-(19), wherein receiving the B1 correction function in the first dimension includes, but is not limited to, calculating a transmission efficiency based on the measurement of reflected RF power across a range of frequencies.

(21) The method according to any one of (1)-(19), wherein receiving the B1 correction function in the first dimension includes, but is not limited to, calculating a transmission efficiency based on B1 amplitude measurement using one or more pickup loops.

(22) An apparatus for adjusting a flip angle of a first non-excitation RF pulse of a pulse sequence including excitation RF pulses and the first non-excitation RF pulse when imaging using a magnetic resonance imaging apparatus, including, but not limited to: processing circuitry configured to perform the steps of any one of (1)-(19).

(23) A non-transitory computer-readable storage medium storing computer-readable instructions that, when executed by a computer, cause the computer to perform a method of any one of (1)-(19).

Thus, the foregoing discussion discloses and describes merely exemplary embodiments of the present disclosure. As will be understood by those skilled in the art, the present disclosure may be embodied in other specific forms without departing from the spirit thereof. Accordingly, the disclosure of the present disclosure is intended to be illustrative, but not limiting, of the scope of the disclosure, as well as other claims. The disclosure, including any readily discernible variants of the teachings herein, defines, in part, the scope of the foregoing claim terminology such that no inventive subject matter is dedicated to the public.

1. A method for adjusting a flip angle of a first non-excitation RF pulse of a pulse sequence including excitation RF pulses and the first non-excitation RF pulse when imaging using a magnetic resonance imaging apparatus, the method comprising:
receiving a B1 correction function in a first dimension;
receiving the pulse sequence including the excitation RF pulses and the first non-excitation RF pulse; and
adjusting the flip angle of the first non-excitation RF pulse based on the received B1 correction function and based on a first spatial position of the first non-excitation RF pulse.

2. The method as claimed in claim 1, further comprising performing imaging using the pulse sequence including the adjusted flip angle of the first non-excitation RF pulse of the pulse sequence.

3. The method as claimed in claim 1, wherein the adjusting the flip angle of the first non-excitation RF pulse based on the received B1 correction function and based on the first spatial position of the first non-excitation RF pulse consists of adjusting the flip angle of the first non-excitation RF pulse based on the received B1 correction function and based on the first spatial position of the RF non-excitation pulse without adjusting flip angles of the excitation RF pulses based on the received B1 correction function.

4. The method as claimed in claim 1, wherein the adjusting the flip angle of the first non-excitation RF pulse based on the received B1 correction function and based on the first spatial position of the first non-excitation RF pulse comprises dividing the flip angle of the first non-excitation RF pulse by a correction factor of the received B1 correction function corresponding to the first spatial position of the first non-excitation RF pulse.

5. The method as claimed in claim 1, wherein the first non-excitation RF pulse precedes at least one of the excitation RF pulses of the pulse sequence.

6. The method as claimed in claim 1, wherein the first non-excitation RF pulse is a spatially-selective RF pulse where selection of the spatially-selective RF pulse is in a same geometry alignment as corresponding imaging slices.

7. The method as claimed in claim 6, wherein the spatially-selective RF pulse is an inversion pulse.

8. The method as claimed in claim 7, wherein the inversion pulse is a FLAIR pulse.

9. The method as claimed in claim 7, wherein the inversion pulse is a STIR pulse.

10. The method as claimed in claim 6, wherein the spatially-selective saturation pulse is an RF pulse for signal presaturation.

11. The method as claimed in claim 6, wherein the spatially-selective RF pulse is a tagging pulse.

12. The method as claimed in claim 6, wherein the spatially-selective RF pulse is a spatial presaturation pulse.

13. The method as claimed in claim 1, wherein receiving the B1 correction function in the first dimension comprises receiving a result of a one-dimensional B1 projection.

14. The method as claimed in claim 1, wherein receiving the B1 correction function in the first dimension comprises receiving results of a set of one-dimensional B1 projections at different distances from the isocenter to produce a B1 correction function in two dimensions.

15. The method as claimed in claim 1, wherein receiving the B1 correction function in the first dimension comprises receiving a result of a frequency response of a transmit coil.

16. The method as claimed in claim 1, further comprising adjusting a flip angle of a second non-excitation RF pulse of the pulse sequence based on the received B1 correction function and based on a second spatial position of the second non-excitation RF pulse.

17. The method as claimed in claim 1, further comprising adjusting a flip angle of a first excitation RF pulse of the pulse sequence based on the received B1 correction function and based on a second spatial position of the first non-excitation RF pulse.

18. The method as claimed in claim 1, wherein receiving the B1 correction function in the first dimension comprising calculating a transmission efficiency based on the measurement of reflected RF power across a range of frequencies.

19. The method as claimed in claim 1, wherein receiving the B1 correction function in the first dimension comprising calculating a transmission efficiency based on B1 amplitude measurement using one or more pickup loops.

20. An apparatus for adjusting a flip angle of a first non-excitation RF pulse of a pulse sequence including excitation RF pulses and the first non-excitation RF pulse when imaging using a magnetic resonance imaging apparatus, comprising:
processing circuitry configured to:
receiving a B1 correction function in a first dimension;
receiving the pulse sequence including the excitation RF pulses and the first non-excitation RF pulse; and
adjusting the flip angle of the first non-excitation RF pulse based on the received B1 correction function and based on a first spatial position of the first non-excitation RF pulse.

21. A non-transitory computer-readable storage medium storing computer-readable instructions that, when executed by a computer, cause the computer to perform a method comprising:
receiving a B1 correction function in a first dimension;
receiving the pulse sequence including the excitation RF pulses and the first non-excitation RF pulse; and
adjusting the flip angle of the first non-excitation RF pulse based on the received B1 correction function and based on a first spatial position of the first non-excitation RF pulse.
